(19) United States
(12) Patent Application Publication
(10) Pub. No.: US 2024/0356295 A1
(43) Pub. Date: Oct. 24, 2024

(54) METHOD FOR INSTALLING A FIRST CONNECTOR, WHICH IS ACTUALLY PROVIDED FOR MOUNTING ALONG A LONGITUDINAL AXIS OF A HOUSING, IN A FIELD DEVICE HOUSING

(71) Applicant: Endress+Hauser SE+Co. KG, Maulburg (DE)

(72) Inventors: Christian Strittmatter, Rickenbach (DE); Simon Gerwig, Schopfheim (DE); Raphael Schonhardt, Rheinfelden (DE); Michael Lais, Schönau im Schwarzwald (DE); Vitogiuseppe Di Cosola, Hartheim (DE)

(21) Appl. No.: 18/687,376

(22) PCT Filed: Jul. 27, 2022
(86) PCT No.: PCT/EP2022/071046

§ 371 Date: Feb. 28, 2024

(30) Foreign Application Priority Data
Aug. 31, 2021 (DE) 10 2021 122 564.7

(51) Int. Cl. H01R 43/26; H01R 12/71; H01R 12/72

(52) U.S. Cl. CPC H01R 43/26; H01R 12/716; H01R 12/722

(57) ABSTRACT

The disclosure relates to a method of installing a first connector for mounting along a longitudinal axis of a housing, in a field device housing, in which the connector is not installed along a longitudinal axis of the field device housing, but parallel to a transverse axis of the field device housing. The method comprises the following steps: providing a first circuit board; providing the field device housing; radially introducing the second circuit board into the field device housing through the housing opening; positioning the first connector of the first circuit board in or at the housing opening; inserting the second rigid connector of the first circuit board into the rigid counterpart connector of the second circuit board; introducing a connector sleeve which precisely fits the first connector into the housing opening and pushing the connector sleeve over the first connector; and welding the connector to the field device housing.

The invention relates to a method for installing a first connector, which is actually provided for mounting along a longitudinal axis of a housing, in a field device housing, and an automation field device having a field device housing obtainable by the method.

Field devices that are used in industrial installations are known from the prior art. Field devices are often used in process automation engineering, as well as in manufacturing automation engineering. In principle, all devices which are process-oriented and which supply or process process-relevant information are referred to as field devices. Field devices are thus used for detecting and/or influencing process variables. Measuring devices, or sensors, are used for detecting process variables. These are used, for example, for pressure and temperature measurement, conductivity measurement, flow measurement, etc., and capture the corresponding process variables of pressure, temperature, conductivity, pH value, fill level, flow etc. Actuators are used for influencing process variables.

These are, for example, pumps or valves that can influence the flow of a fluid in a pipe or the fill level in a tank. In addition to the aforementioned measuring devices and actuators, field devices are also understood to include remote I/Os, radio adapters, or, generally, devices that are arranged at the field level.

A multitude of such field devices is produced and marketed by the Endress+Hauser group.

In hygienic processes, particularly high demands are made with regard to their processing and/or cleanliness. Examples of such hygienic processes are applications in the food industry where there is a risk that deposits and/or impurities can lead to contaminations of foodstuffs that negatively affect the shelf life and/or are harmful to health.

In order to meet these requirements, the housings of the field devices are specially designed. For example, they are manufactured from a metallic material such as 316L stainless steel, and/or designed such that there are as few points as possible at which deposits and/or impurities can adhere.

To connect such field devices, connectors are usually used which are introduced into the housings. In automation systems, so-called circular connectors are often used by means of which data, in particular measurement values, and/or energy are transmitted from the field device to an external unit, for example a higher-level unit. These circular connectors are nowadays often specifically manufactured as special components for the particular field device and integrated into corresponding housing openings. A disadvantage of this variant is that the production of such special components is associated with relatively high costs.

Another variant is the use of a cable assembly obtainable as a standard component which includes not only the circular connector but also a connecting cable already attached to the circular connector. A disadvantage of this variant is that the connecting cable must be manually soldered, clamped, plugged, or screwed to field device electronics by a production worker. In addition, the connection cable also requires a relatively large amount of space in the housing since it must be run from the installation location of the circular connector to the field device electronics and a certain length of the cable also has to be kept available for manual assembly.

Another variant is the use of so-called THT circular connectors (THT stands for through-hole technology). The disadvantage of this variant is that the THT circular connectors usually also have to be attached manually by a production worker. Furthermore, these THT circular connectors require a relatively large amount of space.

The invention is therefore based on the object of specifying a simple and in particular cost-effective option for integrating or mounting a circular connector in a field device housing.

The object is achieved according to the invention by the method according to claim 1 and the automation field device according to claim 7.

The method according to the invention for installing a first connector actually provided for mounting along a longitudinal axis of a housing, in particular a first circular connector, in particular a first M12 circular connector, in a field device housing, wherein the connector is not installed along a longitudinal axis of the field device housing but parallel to a transverse axis of the field device housing, comprises the following steps:
providing a first circuit board on which the first connector is attached in the longitudinal direction on a circuit board edge and which further has at least one second rigid connector which is arranged and attached on the first circuit board in such a way that a plug-in axis of the second rigid connector is inclined/tilted relative to a plane in which the first circuit board is formed, preferably by more than 45°, particularly preferably by approximately 90°;
providing the field device housing which has a substantially rotationally symmetrical region at least in portions, wherein at least one second circuit board is introduced into the field device housing in the region, preferably along the longitudinal axis, wherein the second circuit board has at least one rigid mating connector which corresponds to the second connector of the first circuit board and is arranged and mounted on the second circuit board in such a way that a plug-in axis of the rigid mating connector runs parallel to the longitudinal axis of the field device housing when the second circuit board is inserted into the field device housing, wherein a housing opening for the first circuit board is also provided in the field device housing in a side wall region of the rotationally symmetrical region, wherein the housing opening is dimensioned such that the first circuit board can be inserted radially through the housing opening into the field device housing;
radially introducing the second circuit board into the field device housing through the housing opening;
positioning the first connector of the first circuit board in or at the housing opening;
inserting the second rigid connector of the first circuit board into the rigid mating connector of the second circuit board;
introducing into the housing opening a connector sleeve that precisely fits the first connector and pushing the connector sleeve over the first connector;
welding the connector sleeve to the field device housing.

An advantageous embodiment of the method according to the invention provides that the second circuit board is radially inserted slightly obliquely into the field device housing through the housing opening. For example, the radial introduction can take place at an angle of less than 45°, preferably at an angle of about 30°.

Another advantageous embodiment of the method according to the invention provides the insertion and welding of the connector sleeve to the field device housing only after the introduction or positioning of the first connector.

Another advantageous embodiment of the method according to the invention provides that a circular connector, in particular an M12 circular connector, is used at least as the first connector.

Another advantageous embodiment of the method according to the invention provides that the provided first circuit board has previously been equipped in an SMD assembly line with electronic components corresponding to the intended later function. In particular, the embodiment can provide that the first circuit board has been equipped with electronic components for EMC measures and/or explosion protection measures in the SMD assembly line.

The invention furthermore relates to an automation field device having a field device housing obtainable by the method according to one of the above-described embodiments.

The invention is explained in more detail on the basis of the following drawings. In the figures:

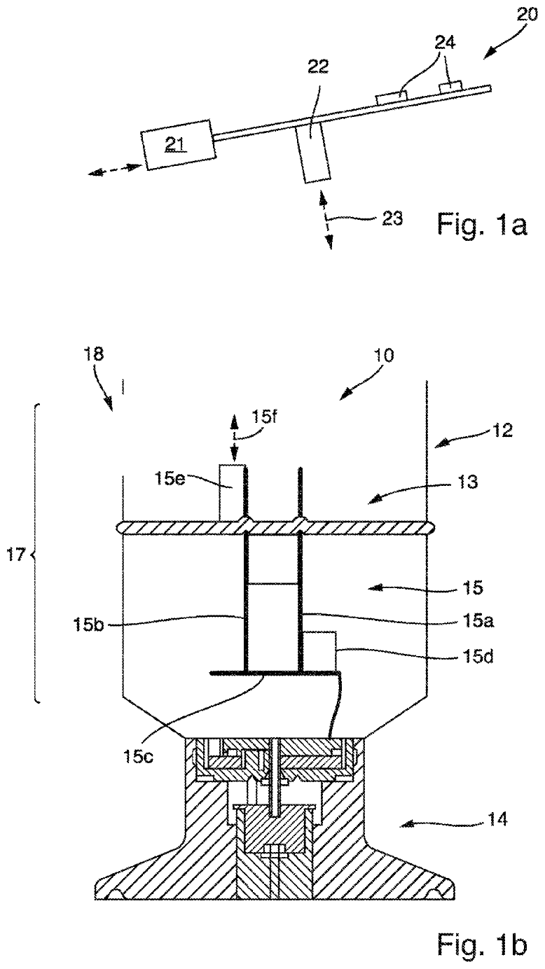

FIG. 1a: shows a first circuit board with a connector which is arranged in the axial direction on a circuit board edge of the circuit board,

FIG. 1b: shows an automation field device,

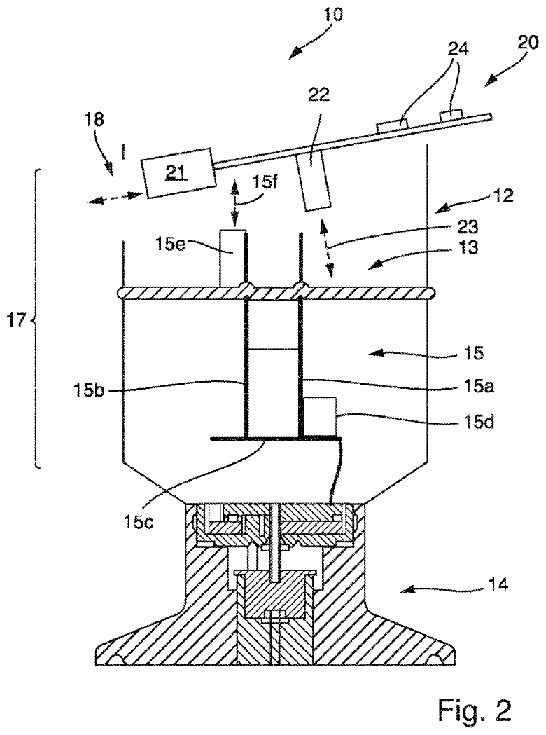

FIG. 2: shows the method step of radial insertion of the circuit board,

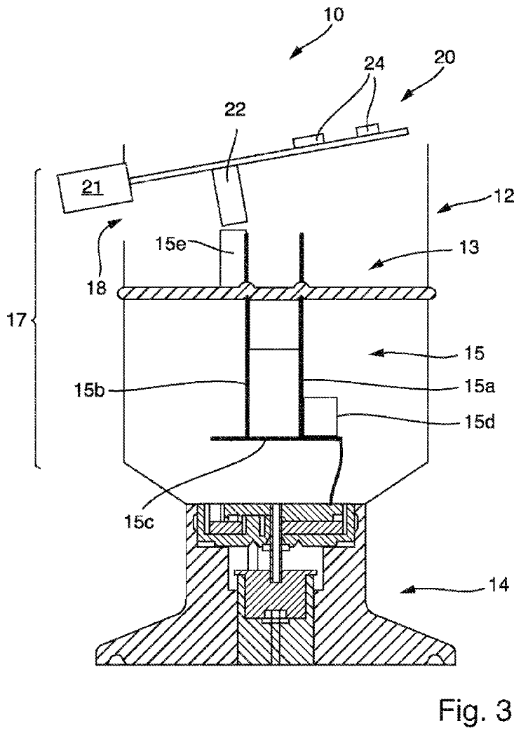

FIG. 3: shows the method step of positioning the circuit board,

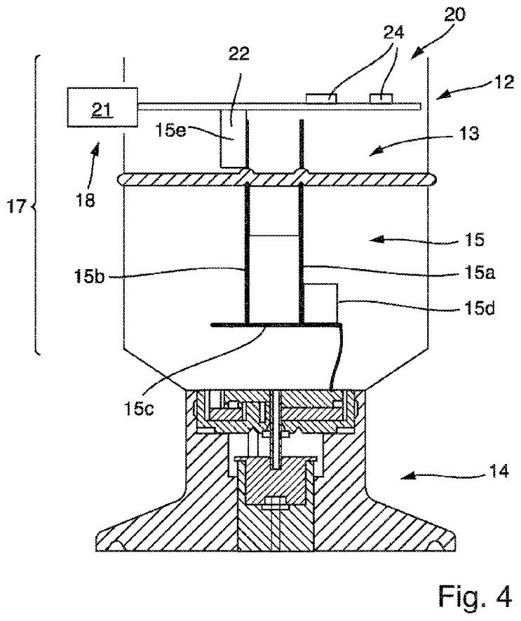

FIG. 4: shows the method step of inserting the connector of the first circuit board into a mating connector of a second circuit board,

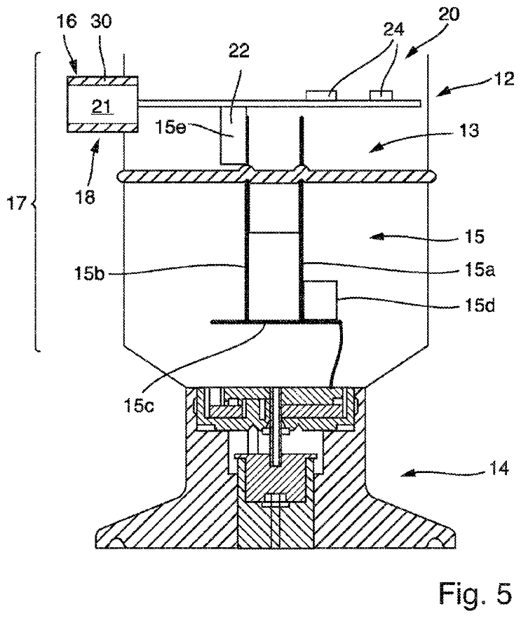

FIG. 5: shows the method step of introducing a precisely fitting connector sleeve into a housing opening of the field device, and

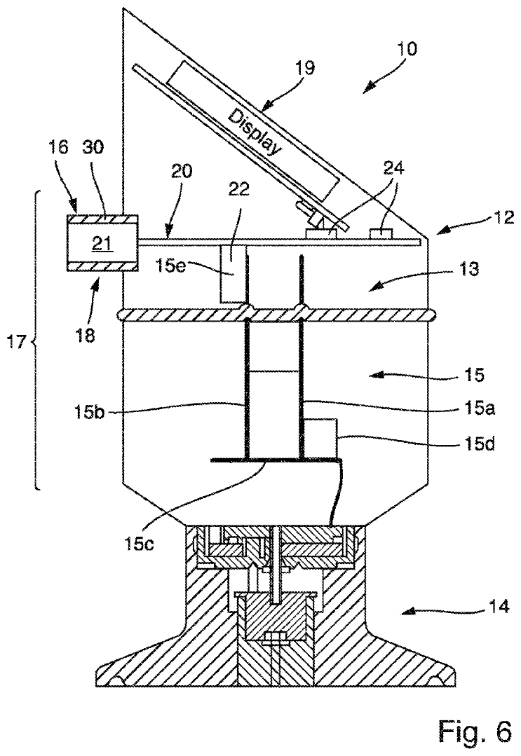

FIG. 6: shows an automation field device produced according to the method according to the invention.

FIG. 1a shows a first circuit board 20 with a connector 21 which is arranged on a circuit board edge in a longitudinal axis of the circuit board 20. Due to the end-side arrangement of the connector 21 in the longitudinal direction of the circuit board 20, it is actually provided for being mounted along a longitudinal axis of a housing, for example of a sensor tube. The connector 21 can in particular be a circular connector, for example an M12 circular connector. Such connectors are known from the company ERNI, for example.

The first circuit board 20 furthermore comprises at least one second rigid connector 22 which is arranged and mounted on the first circuit board 20 in such a way that a plug-in axis 23 of the second connector is inclined or tilted relative to a main plane in which the first circuit board 20 is formed. In the exemplary embodiment shown in FIG. 1, the second connector 22 is inclined with its plug-in axis 23 at 90° to the main plane or the plug-in axis 23 is orthogonal to the main plane. Nevertheless, the second connector does not necessarily have to be inclined by 90°, but can also be inclined by more than 45° relative to the plane, for example.

The first circuit board 20 can have been assembled fully automatically in an SMD assembly line with electronic components and also with the connector in accordance with the later desired or intended function, so that a printed circuit board required for the further method according to the invention is or will be subsequently provided. For example, electronic components for EMC and/or explosion protection measures 24 can be applied to the first circuit board.

FIG. 1b shows a part of an automation field device 1, which comprises a field device housing 12 which encloses an interior space 13. The field device housing 12 has an at least sectionally rotationally symmetrical region 17 into which the connector is to be integrated. The field device housing further comprises a sensor and/or actuator element 14 arranged on the housing 12 for setting and/or capturing a process variable, and an electronic circuit 15 introduced into the interior space 13, which is designed to operate the sensor and/or actuator element 14. In the present exemplary embodiment, the electronic circuit comprises three additional circuit boards of which two circuit boards are arranged in the longitudinal direction of the housing 15a and 15b, and one circuit board 15c in the direction transverse to the housing. The circuit boards 15a, 15b, 15c are plugged into one another via corresponding connectors and mating connectors 15d and are thus electrically contacted. One of the circuit boards 15b which is arranged in the longitudinal direction comprises at least one rigid mating connector 15e which corresponds to the second rigid connector of the first circuit board and is arranged and mounted on this circuit board 15b in such a way that, in the installed state, a plug-in axis of the mating connector runs parallel to the longitudinal axis of the field device housing.

In the region on a side wall, the field device housing furthermore has a housing opening 18 for radially introducing the first circuit board 20. The housing opening 18 is dimensioned such that the first circuit board 20 can be inserted radially through the housing opening 18 into the interior space 13. In particular, the housing opening 18 is dimensioned such that the first circuit board 20 can be inserted slightly obliquely, i.e. inclined by a small angle relative to the horizontal plane.

In the installed state, a field device interface 16 for the field device shown in FIG. 6 is realized with the first circuit board 20 shown in FIG. 1a. In combination with the electronic circuit 15 of the field device 1, depending on the design, the field device interface 16 can either be connected to a two, three or four-wire line, to communicate data, in particular measurement and/or control values, between the electrical circuit and, for example, a higher-level unit.

By means of the method according to the invention, the first circuit board 20 is to be mounted in the radial direction or parallel to a transverse axis 12 of the housing with the connector 21 arranged in the longitudinal direction on a circuit board edge, and is actually provided for mounting along a longitudinal axis of a housing 12. For this purpose, the method provides the following additional steps:

FIG. 2 shows the next method step, which provides that the first circuit board 20 is introduced radially through the housing opening into the field device housing. As shown in FIG. 2, the radial insertion can thereby be slightly oblique, i.e. the first circuit board 20 is introduced inclined by a small angle relative to the transverse axis of the housing 12. For example, the radial introduction can take place at an angle of less than 45° preferably at an angle of about 30°.

FIG. 3 shows the following method step, which provides that the first circuit board 20 is positioned in such a way that the first connector 21 is located in the housing opening 18. In a subsequent step, which is shown in FIG. 4, the second rigid connector 22 of the first circuit board 20 and the mating connector 15e arranged at the end on the printed circuit board 15b already aligned in the longitudinal direction in the field device housing 12 are plugged into one another.

A connector sleeve 30 that precisely fits the first connector 21 is inserted into the housing opening 18 and pushed over the connector 21. In contrast to the method known from the prior art, the housing and the connector sleeve are hence initially realized as two separate components. It is therefore possible to introduce the connector sleeve into the housing after the assembly or introduction of the connector. This in turn enables a non-angled assembly of the plug connector since the precisely-fitting connector sleeve 30 is not yet present at the time of introducing the circuit board. As shown in FIG. 5, the connector sleeve 30 is then welded to the field device housing.

In a final step, the production of the field device is finally completed in accordance with the intended location of use and configuration. This can comprise, for example, the introduction of a display 19 and additional electronic components, as shown by way of example in FIG. 6.

By means of the method described above, an in particular inexpensive automation field device is produced.

### LIST OF REFERENCE SIGNS

10 Automation field device
12 Field device housing
13 Inner chamber
14 Sensor and/or actuator element
15 Electronic circuit
15a, 15c Circuit board
15d Connector and mating connector
15e Rigid mating connector
15f Plug-in axis of the mating connector
16 Field-device interface
17 Rotationally symmetrical region
18 Housing opening
19 Display
20 First printed circuit board
21 First connector
22 Second connector
23 Plug-in axis of the second connector
24 Electronic components, for example for EMC and/or explosion protection measures
30 Connector sleeve

1-7. (canceled)

8. A method for installing a first connector actually provided for mounting along a longitudinal axis of a housing, in particular a first circular connector, in particular a first M12 circular connector, in a field device housing, wherein the connector is not installed along a longitudinal axis of the field device housing, but parallel to a transverse axis of the field device housing, and the method provides the following steps for this purpose:
providing a first circuit board on which the first connector is attached in the longitudinal direction on a circuit board edge and which further has at least one second rigid connector which is arranged and attached on the first circuit board in such a way that a plug-in axis of the second rigid connector is inclined/tilted relative to a plane in which the first circuit board is formed, preferably by more than 45°, particularly preferably by approximately 90°;
providing the field device housing which has a substantially rotationally symmetrical region at least in portions, wherein at least one second circuit board is introduced into the field device housing in the region, preferably along the longitudinal axis, wherein the second circuit board has at least one rigid mating connector which corresponds to the second connector of the first circuit board and is arranged and mounted on the second circuit board in such a way that a plug-in axis of the rigid mating connector runs parallel to the longitudinal axis of the field device housing when the second circuit board is inserted into the field device housing, wherein a housing opening for the first circuit board is also provided in the field device housing in a side wall region of the rotationally symmetrical region, wherein the housing opening is dimensioned such that the first circuit board can be inserted radially through the housing opening into the field device housing;
radially introducing the second circuit board into the field device housing through the housing opening;
positioning the first connector of the first circuit board in or at the housing opening;
inserting the second rigid connector of the first circuit board into the rigid mating connector of the second circuit board;
introducing a connector sleeve that precisely fits the first connector into the housing opening and pushing the connector sleeve over the first connector;
welding the connector sleeve to the field device housing.

9. The method according to claim 8, wherein the second circuit board is radially inserted slightly obliquely into the field device housing through the housing opening.

10. The method according to claim 8, wherein the connector sleeve is inserted and welded on the field device housing only after the first connector has been introduced or positioned.

11. The method according to claim 8, a circular connector, in particular an M12 circular connector, is used at least as the first connector.

12. The method according to claim 8, wherein the provided first circuit board has previously been equipped in an SMD assembly line with electronic components corresponding to the function later intended.

13. The method according to claim 12, wherein the first circuit board has been equipped with electronic components for EMC measures and/or explosion protection measures in the SMD assembly line.

14. An automation field device having a field device housing obtainable by the method according to claim 8.
